(19) United States
(12) Patent Application Publication
(10) Pub. No.: US 2012/0329187 A1
(43) Pub. Date: Dec. 27, 2012

(54) APPARATUS FOR MANUFACTURING ORGANIC LIGHT-EMITTING DISPLAY DEVICE, AND MANUFACTURING METHOD USING THE APPARATUS

(76) Inventors: Sang-Bong Lee, Yongin-City (KR); Myung-Jong Jung, Yongin-City (KR); Min-Soo Shin, Yongin-City (KR); Jin-Woo Park, Yongin-City (KR); Jae-Young Cho, Yongin-City (KR)

(21) Appl. No.: 13/429,248

(22) Filed: Mar. 23, 2012

(30) Foreign Application Priority Data
Jun. 27, 2011 (KR) 10-2011-0062488

(51) Int. Cl. H01L 33/62; B32B 37/02

(52) U.S. Cl. 438/34; 156/379.8; 257/E33.062

(57) ABSTRACT

An apparatus for manufacturing an organic light-emitting display device, and a manufacturing method using the apparatus. An apparatus includes a roll drum unit configured to removably adhere a flexible substrate and a transfer film thereon such that the transfer film overlaps the flexible substrate, and a laser irradiation unit configured to irradiate a laser in a pattern toward the transfer film adhered on the roll drum unit and transfer a transfer layer of the transfer film onto the flexible substrate to form an emission layer.

### CROSS-REFERENCE TO RELATED APPLICATION

This application claims priority to and the benefit of Korean Patent Application No. 10-2011-0062488, filed on Jun. 27, 2011 in the Korean Intellectual Property Office, the entire content of which is incorporated herein by reference.

### BACKGROUND

1. Field

Aspects of embodiments of the present invention relate to an apparatus for manufacturing an organic light-emitting display device, and a manufacturing method using the apparatus.

2. Description of the Related Art

In general, organic light-emitting display devices are advantageous video display media due to their high response speeds, low power consumptions, and large viewing angles. Also, organic light-emitting display devices are regarded as next-generation flat panel display devices due to their low-temperature and simple manufacturing processes based on existing semiconductor process technology.

Typically, flexibility is required to mount organic light-emitting display devices in a bent state. For this, since a hard glass substrate has to be removed, a method of forming a polymer layer on a glass substrate, sequentially forming thin film layers of an organic light-emitting display device (e.g., a thin-film transistor (TFT) layer, an emission layer, and an encapsulation layer) on the polymer layer, and then removing the glass substrate is typically performed. In other words, by removing a glass substrate in a final operation, a flexible polymer layer, instead of the glass substrate, functions as a base substrate.

A laser induced thermal imaging (LITI) method is a common method of forming an emission layer.

The LITI method is a method of bonding a transfer film onto a substrate onto which an emission layer is to be formed, and irradiating a laser according to a desired pattern of the emission layer, thereby transferring a transfer material deposited on the transfer film onto a corresponding location of the substrate to form the emission layer.

However, the LITI method may require a worker to accurately bond the transfer film onto the substrate and to clearly remove the completely used transfer film from the substrate. For example, when a transfer film is bonded onto a substrate, if the alignment therebetween is inaccurate, the transfer film may not be easily removed and then re-bonded because the transfer film can be damaged. Therefore, a worker is required to accurately align the transfer film with respect to the substrate on a first attempt. Furthermore, the worker is also required to clearly remove the completely used transfer film from the substrate.

Accordingly, in view of the above-described problems, there is a need to efficiently and conveniently manufacture flexible organic light-emitting display devices.

### SUMMARY

According to an aspect of embodiments of the present invention, an apparatus for manufacturing an organic light-emitting display device, and a manufacturing method using the apparatus, conveniently and efficiently form an emission layer.

According to an embodiment of the present invention, an apparatus for manufacturing an organic light-emitting display device includes a roll drum unit configured to removably adhere a flexible substrate and a transfer film thereon such that the transfer film overlaps the flexible substrate, and a laser irradiation unit configured to irradiate a laser in a pattern toward the transfer film adhered on the roll drum unit and transfer a transfer layer of the transfer film onto the flexible substrate to form an emission layer.

The roll drum unit may include a roll drum including an outer circumferential surface in which a plurality of through holes are formed, and a central portion formed as a cavity connected to the plurality of through holes; and a suctioning tool configured to apply a suction force through the through holes.

The suctioning tool may include an exhaust pipe connected to the cavity; and a vacuum pump configured to suction air from the cavity through the exhaust pipe.

The roll drum unit may further include a rotation tool configured to rotate the roll drum. The rotation tool may include a relay gear connected to the roll drum; and a driving motor connected to the relay gear.

The laser irradiation unit may include a laser head configured to irradiate a laser; a guide rail configured to guide the laser head to move along a direction parallel to an axial direction of the roll drum unit; and an actuator configured to move the laser head along the guide rail.

According to another embodiment of the present invention, a method of manufacturing an organic light-emitting display device includes: removably adhering a flexible substrate onto an outer circumferential surface of a roll drum; removably adhering a transfer film onto the outer circumferential surface of the roll drum to overlap the flexible substrate; and irradiating a laser toward the transfer film to transfer a transfer layer of the transfer film onto the flexible substrate to form an emission layer.

The method may further include forming the flexible substrate on a glass substrate, and separating the glass substrate and the flexible substrate from each other before adhering the flexible substrate onto the outer circumferential surface of the roll drum.

The flexible substrate may include a polymer layer; a thin-film transistor (TFT) layer formed on the polymer layer; and a pixel electrode that is electrically connected to the TFT layer.

The flexible substrate may further include a hole injection and transport layer formed on the pixel electrode.

The method may further include rotating the roll drum while the laser is irradiated.

The method may further include changing a location at which the laser is irradiated, along an axial direction of the roll drum.

The method may further include bonding a protective film on a surface of the flexible substrate to contact the roll drum, before the flexible substrate is adhered onto the roll drum.

According to an aspect of embodiments of the present invention, when an emission layer is formed using a laser induced thermal imaging (LITI) method, since a flexible substrate and a transfer film are supported by using a vacuum suction force, the alignment between the transfer film and the flexible substrate may be easily adjusted as needed, and the used transfer film may be easily removed by merely blocking the suction force, thereby greatly improving an operational efficiency.

### BRIEF DESCRIPTION OF THE DRAWINGS

The above and other features and aspects of the present invention will become more apparent by describing in detail some exemplary embodiments thereof with reference to the attached drawings in which:

FIG. 1 is a partial cross-sectional view of an organic light-emitting display device according to an embodiment of the present invention;

FIG. 2 is a perspective view of an apparatus for manufacturing an organic light-emitting display device, according to an embodiment of the present invention;

FIG. 3 is a cross-sectional view of a roll drum of the apparatus for manufacturing an organic light-emitting display device of FIG. 2, taken along a line A-A; and

FIGS. 4A through 4F are schematic diagrams illustrating a method of manufacturing an organic light-emitting display device using an apparatus for manufacturing an organic light-emitting display device, according to an embodiment of the present invention.

### DETAILED DESCRIPTION

Some exemplary embodiments of the present invention will be described more fully hereinafter with reference to the accompanying drawings; however, embodiments of the present invention may be embodied in different forms and should not be construed as limited to the exemplary embodiments illustrated and set forth herein. Rather, these exemplary embodiments are provided by way of example for understanding of the invention and to convey the scope of the invention to those skilled in the art. As those skilled in the art would realize, the described embodiments may be modified in various ways, all without departing from the spirit or scope of the present invention.

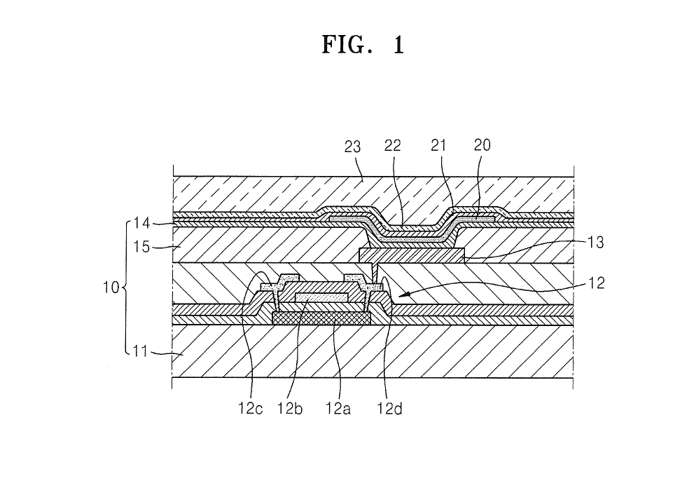

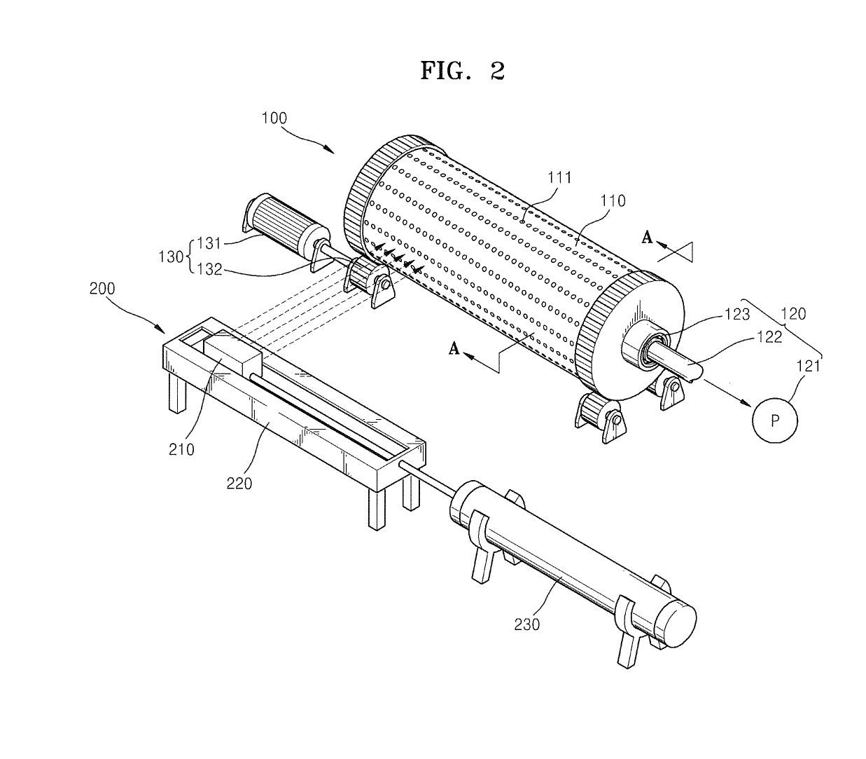

FIG. 2 is a perspective view of an apparatus for manufacturing an organic light-emitting display device, according to an embodiment of the present invention. FIG. 1 is a partial cross-sectional view of an organic light-emitting display device manufactured using the manufacturing apparatus illustrated in FIG. 2.

As illustrated in FIG. 1, the organic light-emitting display device manufactured using the manufacturing apparatus according to an embodiment of the present invention is a flexible organic light-emitting display device from which a glass substrate is removed, and has a structure in which a polymer layer 11, instead of the glass substrate, functions as a base substrate.

In one embodiment, a thin film transistor (TFT) layer 12 including an active layer 12a, a gate electrode 12b, a source electrode 12c, and a drain electrode 12d is formed on the polymer layer 11 functioning as a base substrate, and a pixel electrode 13 that is electrically connected to the drain electrode 12d, a pixel-defining layer 15 for defining a pixel region, and a hole injection and transport layer 14 are formed on the TFT layer 12. Herein, a stack from the polymer layer 11 to the hole injection and transport layer 14 is referred to as a flexible substrate 10, which is a target on which an emission layer 20 is to be formed using the manufacturing apparatus. Manufacturing processes, according to an embodiment of the present invention, including a process of forming the emission layer 20, are described below.

In one embodiment, the emission layer 20, an electron injection and transport layer 21, a counter electrode 22, and an encapsulation layer 23 are sequentially formed on the flexible substrate 10. The encapsulation layer 23 may be formed as a thin film in which, for example, organic and inorganic films are alternately stacked. Accordingly, since a thin film excluding a hard glass substrate is formed from the polymer layer 11 that is a base substrate to the encapsulation layer 23 for sealing, a flexible organic light-emitting display device may be achieved.

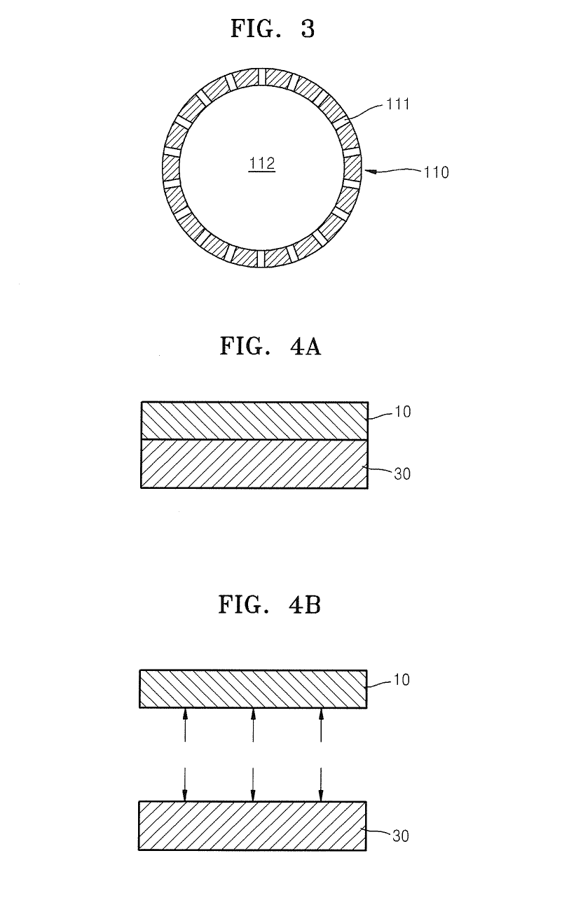

A manufacturing apparatus for manufacturing an organic light-emitting display device, according to an embodiment of the present invention, is described below with reference to FIGS. 2 and 3.

The manufacturing apparatus according to an embodiment of the present invention includes a roll drum unit 100 for mounting the flexible substrate 10 on which the emission layer 20 is to be formed, and a laser irradiation unit 200 for irradiating a laser toward the flexible substrate 10 mounted on the roll drum unit 100 to form the emission layer 20 in a desired pattern by using a laser induced thermal imaging (LITI) method.

The roll drum unit 100, in one embodiment, includes a roll drum 110 that is a cylindrical element, a rotation tool 130 for rotating the roll drum 110, and a suctioning tool 120, or absorption tool, for applying a suction force, or absorption force, to an outer circumferential surface of the roll drum 110.

As illustrated in FIG. 3, a plurality of through holes 111 are formed in the outer circumferential surface of the roll drum 110, and a cavity 112 is formed in a central portion of the roll drum 110 and is connected to the through holes 111. Accordingly, air in the cavity 112 may be suctioned out from the cavity 112, and a negative pressure may thereby be generated in the cavity 112 such that a suction force, or a vacuum suction force, is applied to the outer circumferential surface of the roll drum 110 in which the through holes 111 connected to the cavity 112 are distributed.

The suctioning tool 120 is a tool for applying a suction force to the outer circumferential surface of the roll drum 110 based on the above-described principle, and, in one embodiment, includes an exhaust pipe 122 connected to the cavity 112, and a vacuum pump 121 for suctioning air in the cavity 112 through the exhaust pipe 122. Accordingly, if the vacuum pump 121 is driven, air in the cavity 112 is suctioned out through the exhaust pipe 122, and thus, a suction force is applied to the outer circumferential surface of the roll drum 110 in which the through holes 111 connected to the cavity 112 are distributed. In one embodiment, a ball bearing 123 is arranged to connect the roll drum 110 and the exhaust pipe 122 to each other so that the roll drum 110 may rotate while being combined with the exhaust pipe 122.

The rotation tool 130, in one embodiment, includes a relay gear 132 that is gear-combined with the roll drum 110, and a driving motor 131 for rotating the relay gear 132. Accordingly, if the driving motor 131 is driven, the relay gear 132 and the roll drum 110 that is engaged with the relay gear 132 simultaneously rotate.

The laser irradiation unit 200 according to an embodiment of the present invention includes a laser head 210, a guide rail 220, and an actuator 230.

The laser head 210 is an element for irradiating a laser toward the roll drum 110 according to a desired pattern of the emission layer 20.

The guide rail 220 guides the laser head 210 to slide along a direction parallel to an axial direction of the roll drum 110.

The actuator 230 is an element, such as an air cylinder, for moving the laser head 210 along the guide rail 220.

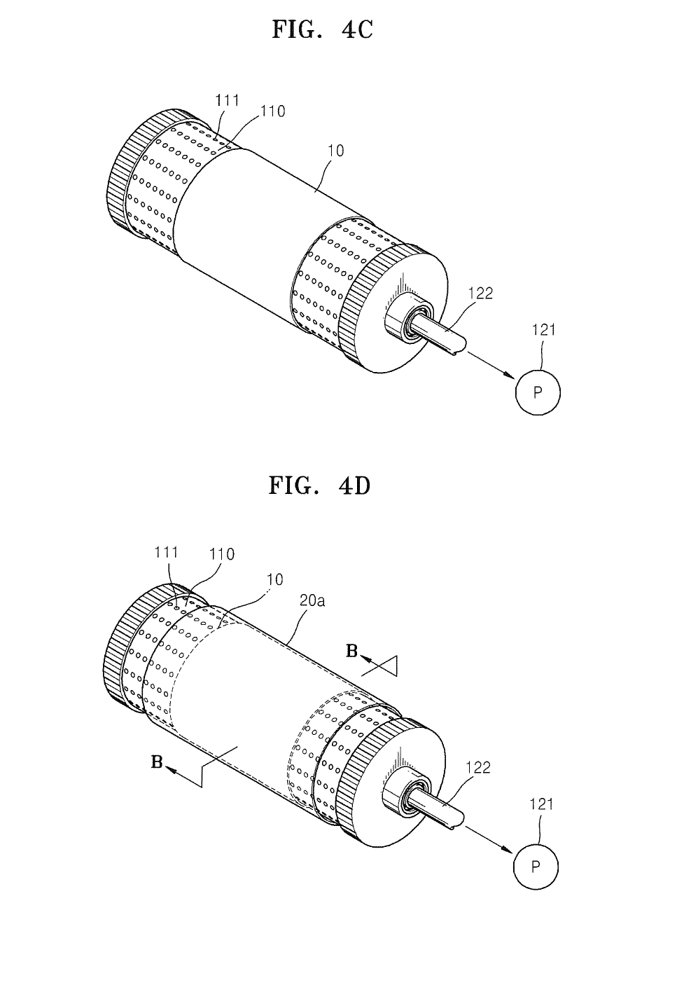

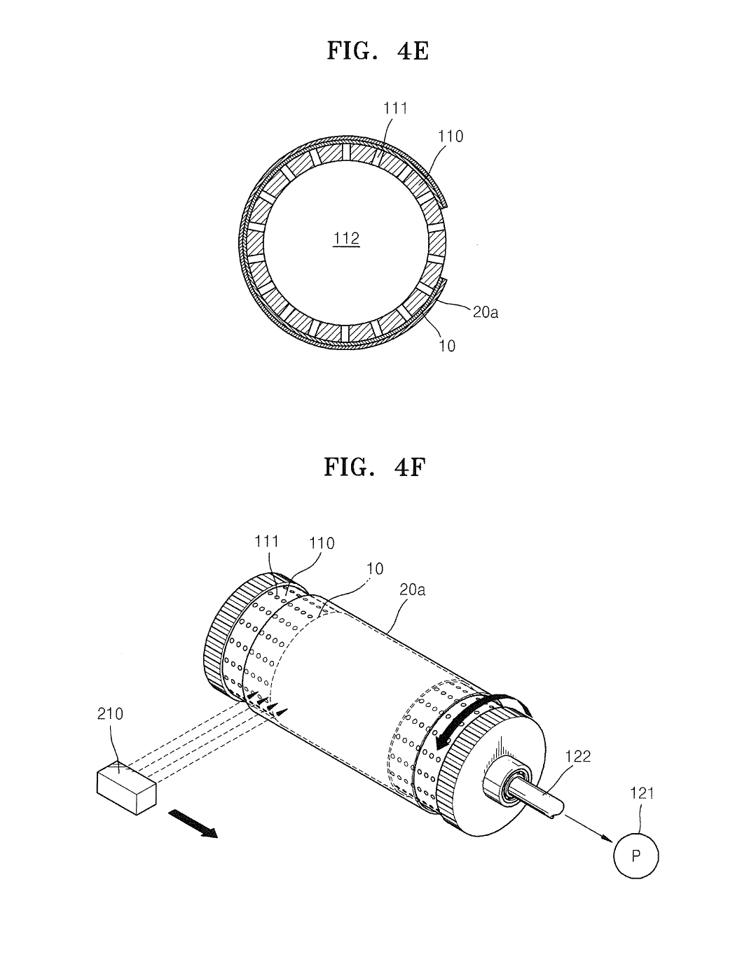

A method of manufacturing an organic light-emitting display device, such as the organic light-emitting display device shown in FIG. 1, by using a manufacturing apparatus, such as the apparatus for manufacturing an organic light-emitting display device illustrated in FIG. 2, according to an embodiment of the present invention, is described below in further detail with reference to FIGS. 4A through 4F.

FIGS. 4A through 4F are schematic diagrams illustrating a method of manufacturing the organic light-emitting display device illustrated in FIG. 1 by using the manufacturing apparatus illustrated in FIG. 2.

Initially, in one embodiment, the flexible substrate 10 is formed on a glass substrate 30. As described above with respect to FIG. 1, the flexible substrate 10 includes the polymer layer 11, the TFT layer 12, the pixel electrode 13, the pixel-defining layer 15, and the hole injection and transport layer 14, and may be formed by performing general coating and deposition processes. For example, the polymer layer 11 may be formed by spin-coating heat-stable polyimide on the glass substrate 30, and the TFT layer 12, the pixel electrode 13, the pixel-defining layer 15, and the hole injection and transport layer 14 may be formed using a deposition method. The flexible substrate 10 is schematically illustrated on the glass substrate 30 in FIG. 4A.

Once the flexible substrate 10 is formed, the emission layer 20 is formed on the flexible substrate 10. Before the emission layer 20 is formed on the flexible substrate 10, the glass substrate 30 and the flexible substrate 10 are separated from each other (e.g., the flexible substrate 10 is removed from the glass substrate 30), as illustrated in FIG. 4B. In the above-described manufacturing apparatus, since a target on which the emission layer 20 is to be formed is mounted on the outer circumferential surface of the roll drum 110 (e.g., in a wound state), a hard element such as the glass substrate 30 is removed before the emission layer 20 is formed. For example, if an ultraviolet ray were irradiated onto a whole surface of the glass substrate 30, the glass substrate 30 may be separated due to a difference in thermal expansion coefficient between the glass substrate 30 and the polymer layer 11.

The flexible substrate 10, from which the glass substrate 30 is separated, is removably adhered (e.g., by a suction force) onto the outer circumferential surface of the roll drum 110 of the manufacturing apparatus as illustrated in FIG. 4C. In FIGS. 4C through 4F, the roll drum 110 and the laser head 210 are mainly illustrated while other components of the apparatus are not shown for purposes of clarity, and a detailed structure of the manufacturing apparatus is described with reference to FIG. 2.

In one embodiment, in order to adhere the flexible substrate 10 onto the outer circumferential surface of the roll drum 110, as illustrated in FIG. 4C, the vacuum pump 121 is driven to suction out air in the cavity 112 through the exhaust pipe 122. A suction force is thereby applied to the outer circumferential surface of the roll drum 110 in which the through holes 111 connected to the cavity 112 are broadly distributed, and the flexible substrate 10 is fixed, or held, onto the outer circumferential surface of the roll drum 110 in a wound or partially wound state due to the suction force. In one embodiment, the polymer layer 11 of the flexible substrate 10 may directly contact the outer circumferential surface of the roll drum 110. In another embodiment, in order to prevent or substantially prevent damage to the polymer layer 11, a protective film (not shown) may be adhered onto the polymer layer 11 before the flexible substrate 10 is removably adhered onto the roll drum 110.

After the flexible substrate 10 on which the emission layer 20 is to be formed is adhered onto the roll drum 110, a transfer film 20a for forming the emission layer 20 is fixed, or removably adhered, onto and overlapping the flexible substrate 10, as shown in FIG. 4D. In one embodiment, the transfer film 20a is also fixed, or adhered, due to the suction force applied through the cavity 112 and the through holes 111. In one embodiment, in order to sufficiently apply a suction force to the transfer film 20a disposed on the flexible substrate 10, the transfer film 20a is formed to have a width greater than that of the flexible substrate 10. As such, since two ends of the transfer film 20a outside the flexible substrate 10 are directly adhered onto the outer circumferential surface of the roll drum 110, a sufficiently adhered state may be maintained. Also, the flexible substrate 10 and the transfer film 20a may be adhered and fixed more stably by forming the through holes 111 with a high density, that is, a large number or total area of holes per area of the circumferential surface of the roll drum 110. In one embodiment, the through holes 111 are spaced apart by a distance equal to or less than 15 mm, and a sufficient suction force may be applied.

The transfer film 20a has a structure in which a photothermal conversion layer and a transfer layer to be transferred to the emission layer 20 are sequentially stacked on a base film. This above-described structure is generally well known by those of ordinary skill in the art and thus will not be described in detail here.

A cross-sectional view of the roll drum 110, around which the flexible substrate 10 and the transfer film 20a are wound, is shown in FIG. 4E.

As illustrated in FIG. 4F, the laser head 210 of the laser irradiation unit 200 irradiates a laser toward the transfer film 20a to form the emission layer 20 in a desired pattern on the flexible substrate 10. Here, for example, the desired pattern is a pattern of the emission layer 20 in which the transfer layer of the transfer film 20a is transferred onto the flexible substrate 10 that corresponds to pixel locations on the pixel electrode 13 as illustrated in FIG. 1. In one embodiment, while the laser head 210 irradiates a laser, the roll drum 110 is rotated by the rotation tool 130 so as to allow the laser to be irradiated onto the whole flexible substrate 10 wound around the outer circumferential surface of the roll drum 110. Also, in one embodiment, after the laser head 210 irradiates a laser onto a certain widthwise portion of the flexible substrate 10 at one location while the roll drum 110 rotates, the actuator 230 is driven to move (e.g., by a slight distance) the laser head 210 along the guide rail 220 to another location such that the laser head 210 may irradiate a laser onto another widthwise portion of the flexible substrate 10 at the new location. In this manner, a transfer operation is performed according to an embodiment of the present invention.

As such, the emission layer 20 is formed on the flexible substrate 10 according to an embodiment of the present invention. After the emission layer 20 is completely formed, driving of the vacuum pump 121 may be stopped such that both the flexible substrate 10 and the transfer film 20a may be easily separated from the roll drum 110. That is, unlike in a conventional apparatus or method, since the transfer film 20a is removably adhered onto (rather than being bonded onto, as in a conventional apparatus or method) the flexible substrate 10, the alignment of the flexible substrate 10 with respect to the roll drum 110 may be easily adjusted by moving (e.g., by a slight distance) the flexible substrate 10 while being adhered onto the roll drum 110, and the flexible substrate 10 may be easily separated when the application of the suction force is stopped, thereby achieving a convenient operation. As such, a burden of accurately aligning on and clearly removing the transfer film 20a from the roll drum 110 may be avoided or reduced.

After the emission layer 20 is formed, the electron injection and transport layer 21, the counter electrode 22, and the encapsulation layer 23 may be sequentially formed using a general deposition method. As a result, the flexible organic light-emitting display device illustrated in FIG. 1 is manufactured.

According to embodiments of the present invention, when the emission layer 20 is formed, since the flexible substrate 10 and the transfer film 20a are supported by using a suction force, the alignment between the transfer film 20a and the flexible substrate 10 may be easily adjusted as needed, and the completely used transfer film 20a may be easily removed by merely stopping application of the suction force, thereby greatly improving an operational efficiency.

While the present invention has been particularly shown and described with reference to some exemplary embodiments thereof, it will be understood by those of ordinary skill in the art that various changes in form and details may be made therein without departing from the spirit and scope of the present invention as set forth in the following claims.

What is claimed is:

1. An apparatus for manufacturing an organic light-emitting display device, the apparatus comprising:
a roll drum unit configured to removably adhere a flexible substrate and a transfer film thereon such that the transfer film overlaps the flexible substrate; and
a laser irradiation unit configured to irradiate a laser in a pattern toward the transfer film adhered on the roll drum unit and transfer a transfer layer of the transfer film onto the flexible substrate to form an emission layer.

2. The apparatus of claim 1, wherein the roll drum unit comprises:
a roll drum including an outer circumferential surface in which a plurality of through holes are formed, and a central portion formed as a cavity connected to the plurality of through holes; and
a suctioning tool configured to apply a suction force through the through holes.

3. The apparatus of claim 2, wherein the suctioning tool comprises:
an exhaust pipe connected to the cavity; and
a vacuum pump configured to suction air from the cavity through the exhaust pipe.

4. The apparatus of claim 2, wherein the roll drum unit further comprises a rotation tool configured to rotate the roll drum.

5. The apparatus of claim 4, wherein the rotation tool comprises:
a relay gear connected to the roll drum; and
a driving motor connected to the relay gear.

6. The apparatus of claim 1, wherein the laser irradiation unit comprises:
a laser head configured to irradiate a laser;
a guide rail configured to guide the laser head to move along a direction parallel to an axial direction of the roll drum unit; and
an actuator configured to move the laser head along the guide rail.

7. A method of manufacturing an organic light-emitting display device, the method comprising:
removably adhering a flexible substrate onto an outer circumferential surface of a roll drum;
removably adhering a transfer film onto the outer circumferential surface of the roll drum to overlap the flexible substrate; and
irradiating a laser toward the transfer film to transfer a transfer layer of the transfer film onto the flexible substrate to form an emission layer.

8. The method of claim 7, further comprising:
forming the flexible substrate on a glass substrate; and
separating the glass substrate and the flexible substrate from each other before adhering the flexible substrate onto the outer circumferential surface of the roll drum.

9. The method of claim 7, wherein the flexible substrate comprises:
a polymer layer;
a thin-film transistor (TFT) layer formed on the polymer layer; and
a pixel electrode that is electrically connected to the TFT layer.

10. The method of claim 9, wherein the flexible substrate further comprises a hole injection and transport layer formed on the pixel electrode.

11. The method of claim 7, further comprising rotating the roll drum while the laser is irradiated.

12. The method of claim 7, further comprising changing a location at which the laser is irradiated, along an axial direction of the roll drum.

13. The method of claim 7, further comprising bonding a protective film on a surface of the flexible substrate to contact the roll drum, before the flexible substrate is absorbed onto the roll drum.
